(19) United States
(12) Patent Application Publication
(10) Pub. No.: US 2025/0372403 A1
(43) Pub. Date: Dec. 4, 2025

(54) INTERCONNECTION SUBSTRATE AND METHOD OF MANUFACTURING SUCH A SUBSTRATE

(71) Applicant: STMicroelectronics International N.V., Geneva (CH)

(72) Inventors: Fanny LAPORTE, Villaz (FR); Jerome LOPEZ, Saint Jean De Moirans (FR)

(73) Assignee: STMicroelectronics International N.V., Geneva (CH)

(21) Appl. No.: 19/305,228

(22) Filed: Aug. 20, 2025

Related U.S. Application Data
(62) Division of application No. 18/118,513, filed on Mar. 7, 2023.

(30) Foreign Application Priority Data
Mar. 11, 2022 (FR) FR2202142

(51) Int. Cl. H01L 21/48; H01L 23/14; H01L 23/373

(52) U.S. Cl. CPC H01L 21/486; H01L 23/145; H01L 23/3737

(57) ABSTRACT

An interconnection substrate includes a thermomechanical support crossed by at least one electric interconnection hole. A first interconnection network is formed on a first surface of the thermomechanical support and a second interconnection network is formed on a second surface of the thermomechanical support. Each interconnection network includes and interconnection level formed by at least one metal track from which at least one metal via extends. The at least one metal track and the at least one metal via are embedded in an insulator layer so that the at least one metal via is flush with a surface of the insulator layer most distant from the thermomechanical support. At least one metal track protrudes from the insulator layer of the last interconnection level. The metal vias are configured to electrically couple together two adjacent levels and/or the last level with the at least one protruding metal track.

### CROSS REFERENCE TO RELATED APPLICATIONS

This application is a divisional of U.S. patent application Ser. No. 18/118,513, now abandoned, which claims the priority benefit of French Application for Patent No. FR2202142, filed on Mar. 11, 2022, the contents of which are hereby incorporated by reference in their entireties to the maximum extent allowable by law.

### TECHNICAL FIELD

The present disclosure generally concerns electronic devices and, more particularly, an interconnection substrate configured to hold and electrically couple an electronic component, for example, an electronic chip, to an electronic circuit.

### BACKGROUND

A substrate configured to hold and electrically integrate, in an electronic circuit, an electronic chip is known, for example, in the art as an integrated circuit substrate (IC substrate).

An integrated circuit substrate may, in particular, be an intermediate product enabling to integrate one or a plurality of integrated circuit chips to a printed circuit board (PCB). It generally comprises an electric interconnection network configured to electrically couple the chip(s) and the PCB.

An example of an integrated circuit substrate may comprise a plurality of metal layers forming metal tracks at least partially insulated from one another by insulating layers, the metal tracks of different levels being coupled by metal vias, said tracks and vias forming an interconnection network within the substrate.

For many applications, for example, for radio frequency (RF) applications, improvements to such a substrate may be desired, for example, to improve its rigidity, its strength, and/or to allow a flexibility in the dimensions and the materials of said substrate, and particularly in the dimensions of the interconnection network.

There is a need for an interconnection substrate and for a method of manufacturing such a substrate, which enables to respond to the previously-described needs for improvement.

There is a need to overcomes all or part of the disadvantages of known substrates.

### SUMMARY

An embodiment provides an interconnection substrate comprising: a thermomechanical support crossed by at least one electric interconnection hole; a first interconnection network on a first surface of the support and electrically coupled to a first end of the at least one electric interconnection hole; and a second interconnection network on a second surface of the support and electrically coupled to the second end of the at least one interconnection hole. Each interconnection network comprises: at least one interconnection level, each interconnection level comprising at least one metal track from which at least one metal via extends, the at least one metal track and the at least one metal via being embedded in an insulator layer so that the at least one via is flush with the surface of said insulator layer most distant from the support; and at least one metal track protruding from the insulator layer of the last interconnection level; the metal vias being configured to electrically couple together two adjacent levels and/or the last level with the at least one protruding metal track.

According to an embodiment, at least one track of the first level of each interconnection network is coupled to one of the two ends of the at least one electric interconnection hole.

An embodiment provides a method of manufacturing an interconnection substrate, the method comprising: providing a thermomechanical support crossed by at least one electric interconnection hole; forming at least one level of a first interconnection network on a first surface of the support and of at least one level of a second interconnection network on a second surface of the support, so that the first interconnection network is electrically coupled to a first end of the at least one interconnection hole and that the second interconnection network is electrically coupled to the second end of the at least one interconnection hole; forming each interconnection level comprising: forming at least one metal track by plating, forming at least one metal via by pillar plating from said at least one metal track, and then coating said at least one metal track and said at least one metal via in a molding resin to form an insulator layer, said coating being configured to make the at least one metal via flush with the surface of said insulator layer most distant from the support; and forming at least one metal track protruding from the insulator layer of the last level of each interconnection network, the metal vias being configured to electrically couple together two adjacent levels and/or the last level with the at least one protruding metal track.

According to an embodiment, the coating comprises a molding step configured to embed the at least one metal track and the at least one metal via, possibly followed by a step of polishing the insulator layer to make the at least one metal via flush with the surface of said insulator layer most distant from the support.

According to an embodiment, each of the first and second surfaces of the thermomechanical support is coated with a first seed layer, and the forming of the first level of each interconnection network comprises: forming at least one first metal track by pattern plating from the first seed layer; forming at least one first metal via by pillar plating from said at least one first metal track; removing at least a portion of the first seed layer, for example, by etching; and then coating said at least one first metal track and said at least one first metal via in a molding resin to form a first insulator layer.

According to an embodiment, the method comprises forming a second level of the first and/or of the second interconnection network, wherein forming comprises: forming a second seed layer on the first insulator layer; forming at least one second metal track by pattern plating from the second seed layer; forming at least one second metal via by pillar plating from said at least one second metal track; removing at least a portion of the second seed layer, for example, by etching; and then coating said at least one second metal track and said at least one second metal via in a molding resin to form a second insulator layer.

According to an embodiment, the method comprises forming at least one third level of the first and/or of the second interconnection network, wherein forming comprises repeating of the previous steps.

According to an embodiment, forming at least one interconnection level, for example, the first level of the first and/or of the second interconnection network, further comprises forming at least one plating line configured to ensure an electric continuity with the outside of the substrate for the forming by plating of a metal track and/or via.

According to a specific embodiment, the method comprises forming a second level of the first and/or of the second interconnection network, wherein forming comprises: forming at least one second metal track by pattern plating on the first insulator layer; forming at least one second metal via by pillar plating from said at least one second metal track; and then coating said at least one second metal track and said at least one second metal via in a molding resin to form a second insulator layer.

For example, in this specific embodiment, each interconnection network which is formed thus comprises, in its first level, a plating line.

According to a specific embodiment, the method comprises forming at least one third level of the first and/or of the second interconnection network, wherein forming comprises repeating the previous steps.

According to an embodiment, plating comprises, for example, an electroplating and/or an electrolytic growth.

According to an embodiment, the pattern and/or pillar plating is performed through a pattern comprising at least one opening.

The following embodiments may apply to the substrate and/or to the method.

According to an embodiment, the first interconnection network and the second interconnection network have a same quantity of levels.

According to an embodiment, the first interconnection network and the second interconnection network have different quantities of levels.

According to an embodiment, the tracks and the vias are made of copper, nickel, tungsten, or aluminum.

According to an embodiment, the molding resin is an epoxy resin and/or a thermosetting resin, for example initially in the form of a powder, of a film, or of a liquid.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a cross-section view of an example of a core laminate substrate;

FIG. 2A is a cross-section view of an example of a molded interconnect substrate assembled to a manufacturing support;

FIG. 2B is a cross-section view of an example of two molded interconnect substrates similar to the substrate of FIG. 2A, separated from the manufacturing support;

FIG. 3 is a cross-section view showing a substrate according to an embodiment;

FIGS. 4A through 4M are cross-section views showing steps of an example of a method of manufacturing a substrate according to the embodiment of FIG. 3;

FIGS. 5A through 5F are cross-section views showing steps of another example of a method of manufacturing a substrate according to another embodiment;

FIG. 6 is a cross-section view illustrating a complementary step of a variant of a method of manufacturing a substrate according to another embodiment;

FIG. 7 is a cross-section view showing a substrate according to another embodiment; and

FIG. 8 is a cross-section view showing an electronic circuit comprising a substrate according to an embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the manufacturing of the core is not detailed. Further, an interconnection network may comprise other conductive lines than the tracks and vias described in the present disclosure, as known by those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

In the following description, when reference is made to a “track” or “metal track”, reference is more widely made to any substantially horizontal metal pattern in an electric interconnection network, which further comprises substantially vertical vias, or metal vias, to couple tracks together. A track may thus consist of, or be designated as, a narrow metal deposition (thin track, having a width typically in the range from 5 to 50 μm), a metal plane, and/or a metal pad, for example, a metal pad under a via.

When reference is made to a “selective” metal deposition or to a “pattern” plating, reference is made to a local metal deposition or to a local plating, generally through openings in a pattern, conversely to a full (or continuous) metal deposition or to a panel (or continuous) plating.

Unless specified otherwise, the expressions “around”, “approximately”, “substantially” and “in the order of” signify within 10%, and preferably within 5%.

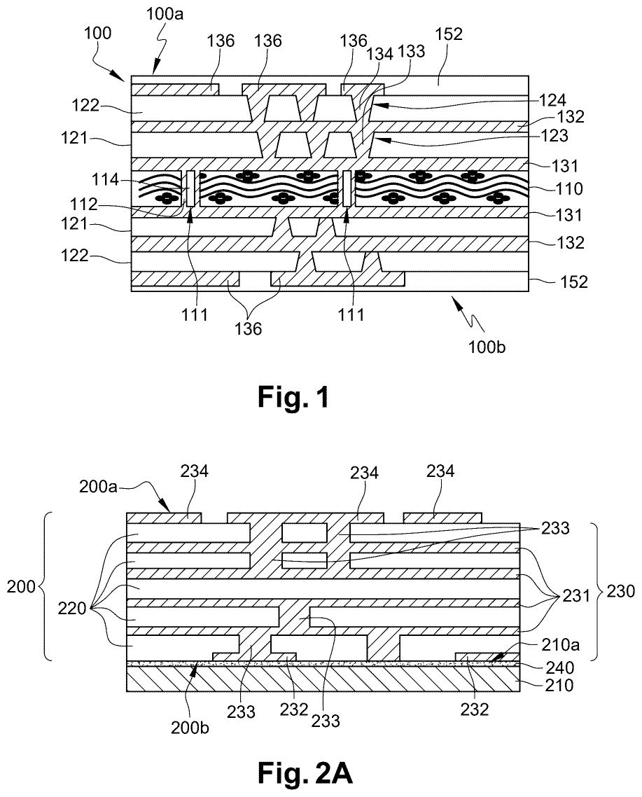

An example of a substrate 100, illustrated in FIG. 1, is a core laminate substrate.

Substrate 100 is formed by starting from a core 110. Core 110 is typically a layer of an organic material, for example, a pre-impregnated material or an epoxy resin, reinforced with fibers, for example, glass fibers. Core 110 is bored with a plurality of through holes 111, the walls of each hole being coated with metal 112 and the hole being filled with an insulating material 114, forming electric interconnection holes. Each surface of core 110 is coated with a first metal layer 131, generally a metal sheet. The core is thus plated on each of its surfaces.

A stack of a first insulator layer 121 topped with a second metal layer 132 is deposited on each first metal layer 131, that is, on each plated surface of core 110, after which the stack is rolled under heat and/or pressure.

This stack is then bored, for example, by laser or mechanical drilling, to form through holes 123, said holes being then filled with metal to form first metal vias 133 therein, enabling to electrically connect the metal tracks (formed by the metal layers) of two consecutive levels together.

A second insulator layer 122 may be formed on each second metal layer 132, generally topped with a third metal layer (not shown), this new stack being rolled and then bored to form through holes 124, said holes being then filled with metal to form second vias 134.

A plurality of metal and insulator layers bored with holes and filled with metal to form vias can thus be formed on each surface of the core. There have been shown two stacks on each surface of the core in FIG. 1, but there might be a single stack on one and/or the other of the surfaces, or more than two.

Each last metal layer (the third one in the described example) is generally used as a base to form discontinuous metal tracks 136 protruding from the upper surface 100a and the lower surface 100b of the substrate. These protruding metal tracks 136 are generally formed by pattern plating, generally by depositing on each third metal layer a resin pattern comprising openings, and then by depositing the metal through these openings. Generally, after removal of the pattern, the third metal layer is etched all the way to the second insulator layer 122 at the locations left empty by the removal of the pattern, to suppress short-circuits risks.

A solder mask layer 152 may then be formed on each surface of the substrate to protect protruding metal tracks 136. Each solder mask layer may be removed afterwards and/or be partially etched to define areas of access to tracks 136.

According to an example, the metal is copper.

The insulator is typically a pre-impregnated material or a resin, for example, an epoxy resin. According to an example, the insulator is an Ajinomoto Build-up Film (ABF) resin.

The core 110 enables to rigidify the laminate substrate and thus, for example, to decrease the deformation and/or the fragility of said substrate.

However, this laminate substrate and its manufacturing method generally do not allow much flexibility in the shapes and dimensions of the vias, in the thicknesses and the widths of the metal tracks, and/or in the pitches between metal tracks. Further, this laminate substrate requires using a significant quantity of pre-impregnated material or of resin, for example, of ABF resin, and it is often not possible to use an alternative material in such a lamination manufacturing method. This makes the manufacturing of such a substrate dependent on a material that may be strongly demanded, with as a consequence an increase in the cost of said material and thus in the substrate manufacturing price.

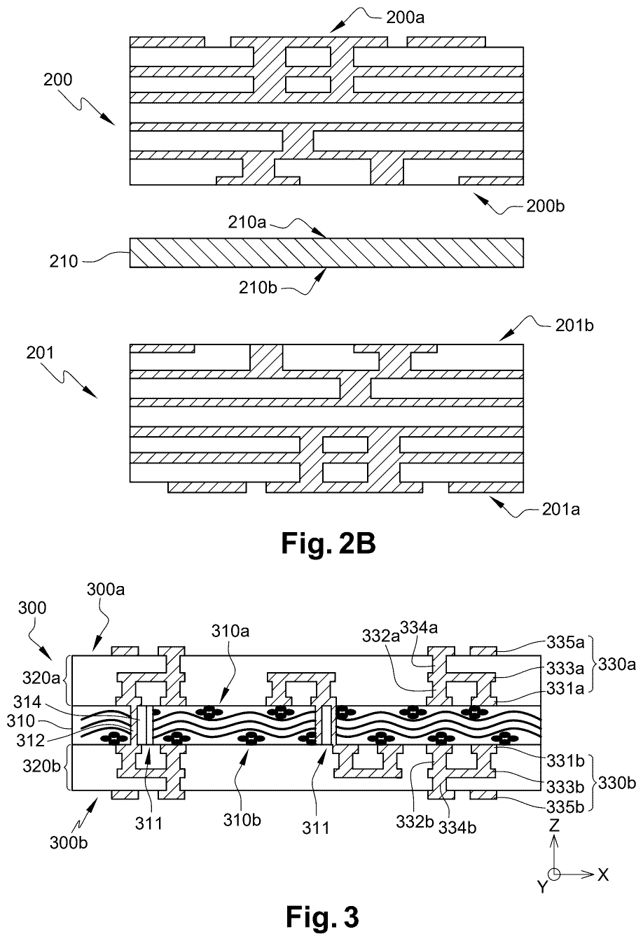

Another example of substrate 200, 201 and a method of manufacturing such a substrate, illustrated in FIGS. 2A and 2B, is a molded interconnect substrate.

Substrate 200, 201 is formed by starting from a metal support 210 comprising an upper surface 210a and a lower surface 210b.

Continuous 231 and discontinuous 232, 234 metal tracks are formed from support 210, either on one surface 210a of support 210 (FIG. 2A), or on both surfaces 210a, 210b of support 210 (FIG. 2B), the metal tracks of two consecutive levels being separated by a resin insulator layer 220 crossed by metal vias 233 enabling to connect said tracks together. The assembly of tracks and vias forms an electric interconnection network 230 having a plurality of levels.

On the lower surface 200b, 201b of the substrate (surface initially in contact with support 210) and on the upper surface 200a, 201a of the substrate, the formed metal tracks 232, 234 are preferably discontinuous, to avoid the risk of short-circuit. For the lower surface of the substrate, it is generally started from a thin continuous metal layer 240 deposited on support 210, forming a bonding and seed layer, this layer being removed after the separation of the support.

A metal layer and/or a metal track may be formed by a panel plating technique and/or by a pattern plating technique, for example, through openings, or plating areas, in a pattern formed by a photolithography technique.

The metal vias are formed by a pillar plating technique, each via being formed from a metal track. In the same way as for pattern plating, pillar plating may be selectively performed through openings in a pattern formed by a photolithography technique.

A plating technique may comprise, for example consist of, an electroplating and/or an electroless deposition, allowing a metal growth from a seed layer, in the presence of an electric power supply (electroplating) or not (electroless).

When a level of the interconnection network is formed (comprising the metal track(s) and the via(s)), a resin layer 220 molds the track/via assembly. The molding resin layer thus formed may then be polished to make each via 233 flush with the surface of said resin layer, possibly before forming another level of the interconnection network on said surface of said resin layer.

For example, the metal of the tracks and of the bonding and seed layer is copper, and the molding resin is an epoxy resin.

Then, each substrate 200, 201 is separated from support 210, and bonding and seed layer 240 is removed, for example, by etching, to avoid the risk of short-circuit.

This molded substrate and its manufacturing method allow more flexibility in the shapes and dimensions of the vias, in the thicknesses and the dimensions of the metal tracks, and in the thicknesses of the insulating layers.

Further, this laminate substrate enables to use insulating materials other than pre-impregnated material or ABF-type resin. It indeed enables to select a resin from among molding resins, which may further be more available and/or have other advantageous properties (for example, thermal, mechanical, electrical, etc.).

However, this substrate is less strong and/or less rigid than a laminate core substrate and may for example exhibit more risks of deformation, or even of breakage, particularly with temperature. To avoid deforming it, or even breaking it, the substrate dimensions are generally limited.

The inventors provide a substrate and a method of manufacturing such a substrate enabling to respond to the previously-described needs for improvement, and to overcome all or part of the disadvantages of the previously-described substrates. In particular, the inventors provide a substrate and a method of manufacturing such a substrate enabling to rigidify and/or to strengthen the substrate, for example to decrease the risk of deformation and/or of breakage of said substrate, while permitting more flexibility in the shapes and dimensions of the vias, in the thicknesses and the widths of the metal tracks, in the pitches between metal tracks, and in the selection and the dimensions of the insulating material.

Embodiments of a substrate and examples of methods of manufacturing a substrate according to an embodiment will be described hereafter. The described embodiments are non-limiting and various variants will occur to those skilled in the art based on the indications of the present disclosure. It can be spoken of an interconnection substrate, for example, of an integrated circuit substrate.

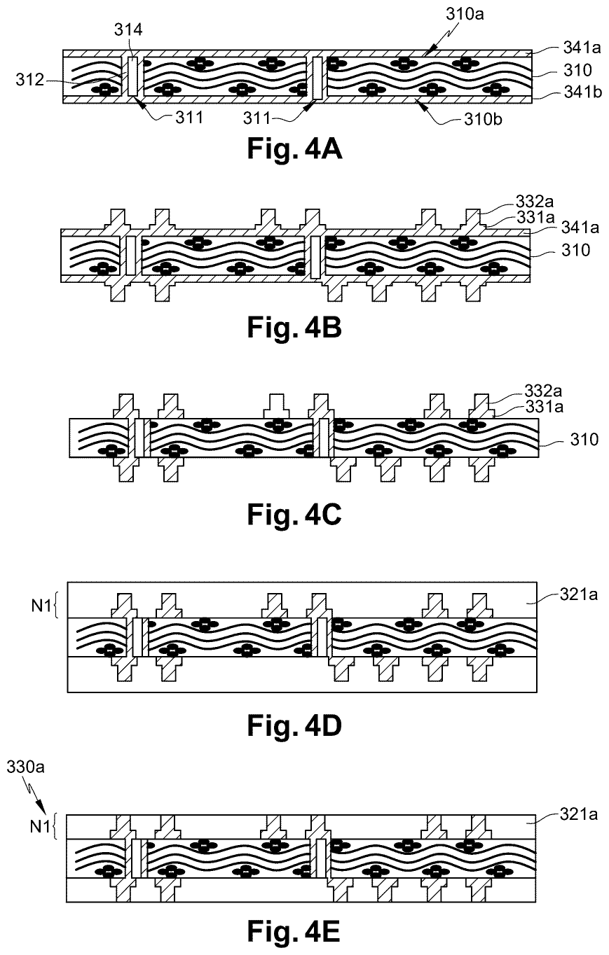

FIGS. 3 to 7 are XZ cross-section views taken at a given height along the Y direction, the vias are not all shown in these drawings, certain vias being formed at another dimension along the Y direction. Further, although this is not shown in the drawings, those skilled in the art will understand that the tracks also extend along the Y direction over a given length.

Further, when reference is made to a height or to a thickness, reference is made to a dimension in the Z direction indicated in the drawings, and when reference is made to a width, reference is made to a dimension in the X direction indicated in the drawings.

FIG. 3 is a cross-section showing a substrate 300 according to an embodiment.

Substrate 300 comprises a core 310 (thermomechanical support) comprising two opposite surfaces: an upper surface 310a (first surface) and a lower surface 310b (second surface). Core 310 may be a layer or multilayer made of an organic material, for example, a pre-impregnated material or an epoxy resin, reinforced with fibers, for example glass fibers, a ceramic material, or a pre-impregnated and copper multilayer.

Core 310 is bored with a plurality of through holes 311 coupling its two opposite surfaces 310a, 310b. The lateral walls of each hole 311 are coated with a metal coating 312 and the holes are filled with an insulating material 314, forming electric interconnection holes crossing the core.

On each surface 310a, 310b of core 310, substrate 300 comprises an electric interconnection network 330a, 330b configured to form an electric continuity between the core, in particular between the interconnection holes 311 of the core, and each of the upper 300a and lower 300b surfaces of the substrate, to form an electric continuity between said upper and lower surfaces of the substrate.

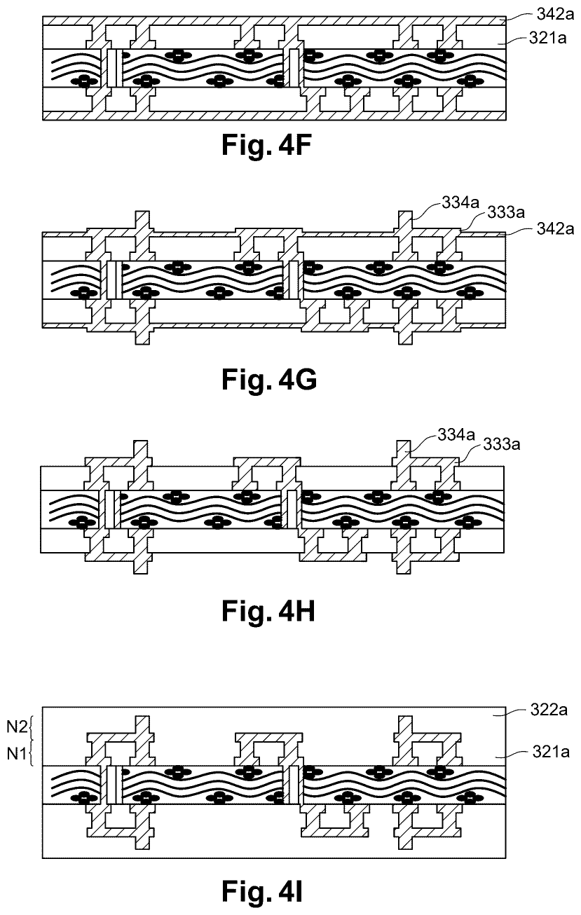

Each interconnection network 330a, 330b comprises one or a plurality of interconnection networks (for example, two levels N1, N2 shown in FIG. 4M), each level comprising at least one substantially horizontal metal track 331a, 333a, 331b, 333b from which at least one substantially vertical metal via 332a, 334a, 332b, 334b extends, the track/via assembly of said level being embedded in a molding resin insulator layer having a height configured so that each via is flush with the free surface of the insulator layer, that is, the thickness of the insulator layer of a level is substantially equal to the height of the vias, plus the thickness of the tracks, of the same level.

It is considered in the embodiments that the first level of an interconnection network is the level closest to the core and that the last level is the level most distant from the core. Of course, if there is a single level, the first level is the same as the last level. Similarly, the first track(s), the first via(s), and the first insulator layer correspond to the first level of an interconnection network, and the last track(s), the last via(s), and the last insulator layer correspond to the last level of an interconnection network.

At least one first track of each interconnection network is coupled, for example, connected, to the electric interconnection holes 311 crossing core 310.

Each interconnection network 330a, 330b further comprises, on the upper surface 300a (first surface) of the substrate or on the lower surface 300b (second surface) of the substrate, metal tracks 335a, 335b protruding from the last formed insulator layer 322a, 322b (shown in FIG. 4M).

In other words, substrate 300 comprises, on each surface 310a, 310b of core 310, a stack 320a, 320b of at least one molding resin insulator layer having tracks and vias of an interconnection network 330a, 330b formed therein and having metal tracks 335a, 335b protruding from interconnection network 330a, 330b formed thereon.

The metal vias of each interconnection network are configured to electrically couple two consecutive interconnection levels and/or the last interconnection level with said protruding metal tracks.

In the shown embodiment, protruding metal tracks 335a, 335b are not embedded in a resin, which enables, for example, to electrically couple the substrate with another component and/or to couple two components together via said substrate.

The metal tracks may be formed by a panel plating technique and/or by a pattern plating technique, for example, through openings, or plating areas, in a pattern formed by a photolithography technique.

Each metal via is formed by a pillar plating technique from a metal track forming a seed layer. In the same way as for pattern plating, pillar plating may be selectively performed through openings in a pattern formed by a photolithography technique, generally another pattern, with finer openings, than the pattern used for the metal track from which the via is formed.

A plating technique may comprise, for example consist of, an electroplating or an electroless deposition, allowing a metal growth from a seed layer, in the presence of an electric power supply (electroplating) or not (electroless).

The metal may be copper, nickel, tungsten, or even aluminum.

The metal tracks may have thicknesses in the range from approximately 10 to 100 micrometers.

The metal vias may have heights in the range from approximately 10 to 100 micrometers.

The insulator layers may be formed by means of a technique of molding of each level of an interconnection network (track(s) and via(s) of each level) with an adapted molding resin, to insulate horizontally the metal tracks from one another and vertically the vias from one another. The molding is optionally followed by a polishing so that each via is flush with the free surface of the insulator layer, where the molding/polishing assembly can be designated by the term coating.

The molding resin maybe an epoxy resin and/or a thermosetting resin. The molding resin may, for example, initially be in the form of a powder configured to be melted, of a film or of a liquid, according to the implemented molding technique.

The substrate according to an embodiment, as well as the method of manufacturing said substrate, enable to obtain a more rigid and stronger substrate, due to the presence of the core held within said substrate, while allowing more flexibility in the shapes and dimensions of the vias, in the thicknesses and the dimensions of the metal tracks, or even in the thicknesses of the insulating layers, due to the use of the plating and molding techniques.

Further, the substrate and the manufacturing method according to an embodiment enable to use as an insulating material a resin selected from among molding resins, which enables to have a wide choice of insulating materials, and may further provide the substrate with advantageous properties (for example, thermal, mechanical, and/or electrical).

In other words, the substrate and the manufacturing method according to an embodiment enable to combine the advantages of the two previously-described laminate core substrate and molded interconnect substrate techniques, or at least to limit the disadvantages of each of said techniques, by keeping the core for the strength and/or the rigidity of the substrate, while taking advantage of the molded interconnect substrate technique.

However, a difficulty in such a combination is due to the fact that the metal bonding and seed layer cannot be removed, conversely to what can be done in the previously-described molded interconnect substrate technique, where the support is separated from the substrate, and the surface of the substrate covered with this metal bonding and seed layer is then accessible so that it can be easily removed. The inventors have thus developed a manufacturing method configured to form an interconnection network between the core and each lower and upper surface of the substrate, while avoiding generating a short-circuit.

Examples of the manufacturing method are given in the following description. These examples are described by taking copper as an example of a metal, knowing that the manufacturing method may be adapted by those skilled in the art for the use of other metals.

To avoid burdening the present description, the steps of forming of interconnection network 330a on the upper surface 310a of core 310 (upper interconnection network, or first interconnection network) are mainly described, knowing that the steps of forming of interconnection network 330b on the lower surface 310b of the core (lower interconnection network, or second interconnection network) are similar, and may be carried out simultaneously to, or alternately to, those of the upper interconnection network. Those skilled in the art will be capable of adapting the description to form lower electric interconnection network 330b from the indications given for upper interconnection network 330a, also based on the drawings.

FIGS. 4A to 4M are cross-section views showing steps of an example of a method of manufacturing a substrate 300 according to the embodiment of FIG. 3.

FIG. 4A illustrates the initial structure, comprising a core 310 bored with a plurality of through holes 311. The lateral walls of each hole 311 are coated with a metal coating 312, and the holes thus coated are filled with an insulating material 314, forming electric interconnection holes crossing the core. Further, each upper and lower surface 310a and 310b of the core is coated with a thin copper layer 341a, 341b, forming a first bonding and seed layer.

According to an example, core 310 is provided with the thin copper layers 341a, 341b. According to another example, core 310 is not provided with the thin copper layers. In this case, the thin copper layers may be formed, for example, by rolling a copper sheet on each surface of the core, or by depositing a bonding layer and then a seed layer, for example, by an electroless deposition.

It should be specified that, when reference is made to a layer in the present description, it may be a monolayer or a multilayer.

To avoid burdening the rest of the description, when reference is made to a seed layer, it may be a bonding and seed layer, generally a multilayer.

For example, the first bonding and seed layer, as well as the bonding and seed layers described in the rest of the present description, have a thickness in the order of one micrometer.

FIG. 4B illustrates a structure obtained at the end of: a first step of Cu pattern plating from the first seed layer 341a, for example, through openings (plating areas) in a pattern previously formed by a photolithography technique on said first seed layer, to form first copper tracks 331a; and then a first Cu pillar plating from each first copper track 331a (forming a seed layer), for example, through openings (copper growth areas) in a pattern, to form first copper vias 332a.

The Cu pattern plating may comprise, or consist of, an electroplating/electrolytic growth technique, which requires for the seed layer to be coupled to an electric source. When the pattern plating is performed by using a pattern with openings, said openings may for example be filled with an electroplating bath. For example, the electroplating technique enables to obtain thicknesses ranging from some ten to some hundred micrometers within a reasonable time.

As a variant, the Cu pattern plating may comprise, or consist of, an electroless deposition technique, where the seed layer is then not necessarily coupled to an electric source. For example, the electroless technique enables to obtain thicknesses in the order of one micrometer within a reasonable time.

The Cu pillar plating may comprise, or consist of, an electroplating/electrolytic growth technique. In the same way as for the pattern plating, the pillar plating may be selectively performed through openings in a pattern formed by a photolithography technique, generally another pattern than that formed to form the copper track from which the via is formed.

FIG. 4C illustrates a structure obtained at the end of a first step of etching of first seed layer 341a. This etching is adapted to etching and removing the copper from said first seed layer, without for all this removing the copper of the first tracks 331a and first vias 332a. This is made possible particularly due to the small thickness of the seed layer. This etch step is, for example, a wet acid etching.

FIG. 4D illustrates a structure obtained at the end of a first step of molding of the first tracks 331a and of the first vias 332a by means of a molding resin, thus forming a first insulating layer 321a on top of and around said first metal tracks and said first vias. The quantity of molding resin used must be sufficient for the metal tracks and the vias to be buried in said insulating resin layer. Thus, the thickness of the resin layer is greater than or equal to the height of the first level N1 of network 330a. According to the shown example, the thickness of the resin layer is greater than the height of the first level N1 of network 330a. In other words, first insulating layer 321a extends heightwise beyond first vias 332a.

In the considered example, the molding step implements a resin in the form of a powder poured on the tracks and the vias, melted, and then hardened. According to another example, the molding step may implement a rolled resin film on the tracks and the vias, which is particularly adapted to a structure of large dimensions. According to still another example, the molding step may implement a liquid thermosetting resin which is cast on the tracks and the vias, and then hardened by heating.

FIG. 4E illustrates a structure obtained at the end of a first step of polishing of the first molding resin insulating layer 321a, so that the first vias 332a are flush with the surface thus polished of said first insulating layer. According to an example, this polishing step implements a mechanical polishing and/or a chemical-mechanical polishing.

A first level N1 of interconnection network 330a is thus obtained. A second level N2 can then be formed by repeating again the steps of FIGS. 4A to 4E as described in the following in relation with FIGS. 4F to 4J.

FIG. 4F illustrates a structure obtained at the end of a step of deposition of a second thin copper layer 342a forming a second seed layer on first insulating layer 321a. This second seed layer may be formed by depositing a bonding layer and then a seed layer, for example, by an electroless deposition.

FIG. 4G illustrates a structure obtained at the end of a second step of Cu pattern plating, from the second seed layer 342a to form second copper tracks 333a, similarly to the first Cu pattern plating; and then of a second step of Cu pillar plating from each second copper track 333a, to form second copper vias 334, similarly to the first Cu pillar plating step. Second tracks 333a may be wider than first tracks 331a, as shown, for example to couple two first tracks together via first metal vias.

FIG. 4H illustrates a structure obtained at the end of a second step of etching of the second seed layer 342a, similarly to the first etch step.

FIG. 4I illustrates a structure obtained at the end of a second step of molding of second tracks 333a and of second vias 334a by means of the molding resin, thus forming a second insulating resin layer 322a, similarly to the first molding step.

FIG. 4J illustrates a structure obtained at the end of a second step of polishing of the second molding resin layer 322a, similarly to the first polishing step.

A second level N2 of interconnection network 330a is thus obtained.

FIG. 4K illustrates a structure obtained at the end of a step of deposition of a third thin copper layer 343a forming a third seed layer on second insulating layer 322a, similarly to the step of deposition of second seed layer 342a.

FIG. 4L illustrates a structure obtained at the end of a third step of Cu pattern plating from the third seed layer 343a to form third copper tracks 335a, similarly to the first pattern plating step.

FIG. 4M illustrates a structure obtained at the end of a third step of etching of third seed layer 343a, similarly to the first etch step. Third copper tracks 355a form protrusions above second insulator layer 322a, and are not embedded in the molding resin.

The obtained structure, shown in FIG. 4M, is similar to the structure of the substrate 300 of FIG. 3.

A plurality of structures may thus be simultaneously and similarly manufactured in the two direction of the XY plane, within an array of structures. This may in particular enable to share electric links to perform electroplatings. The array may be a panel. A panel may be cut into a plurality of strips. The panel or the strips may be cut into a plurality of units, for example, by cutting a strip or a panel flush with each unit structure, as illustrated by the arrows in dotted lines.

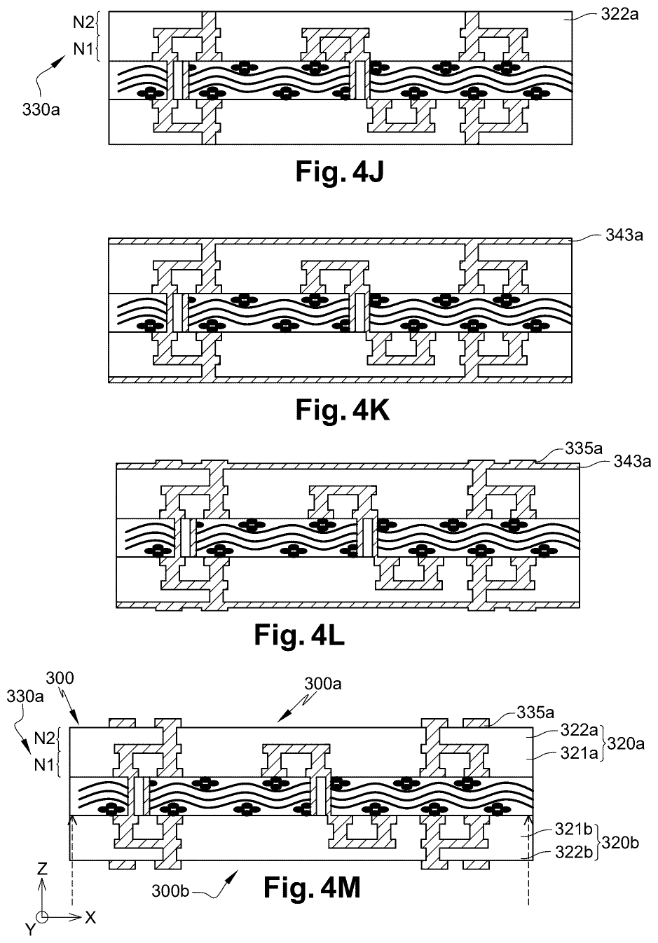

FIGS. 5A to 5F are cross-section views showing steps of another example of a method of manufacturing a substrate 500 according to an embodiment.

This other example of a method can be distinguished from the example of FIGS. 4A to 4M mainly in that no seed layer is deposited from the second interconnection level, and in that plating lines are formed at edges of the structure at the same time as the copper tracks at the first interconnection level.

A plating line is adapted to ensuring an electric continuity between a seed metal layer (or a metal track forming a seed layer) and an electric source external to the structure, for example when a plating is performed by an electroplating/electrolytic growth technique, and when there is no continuous seed layer all the way to an edge of the structure to ensure such a continuity. On a same level and/or from one level to another, this electric continuity may be completed by an arrangement of metal tracks and/or of metal vias already formed in the structure and coupled to at least one plating line.

It is started from the same structure as that described in relation with FIG. 4A: the initial structure comprises a core 510 bored with a plurality of through holes 511. The lateral walls of each hole 511 are coated with a metal coating 512, and the holes thus coated are filled with an insulating material 514, forming electric interconnection holes crossing the core. Further, each upper and lower surface 510a and 310b of the core is coated with a thin copper layer 541a, 541b, forming a first bonding and seed layer.

FIG. 5A illustrates a structure obtained at the end of a first step of Cu pattern plating on the upper surface 510a of core 510, to form first copper tracks 531a, as well as plating lines 536a at edges of the structure.

FIG. 5B illustrates a structure obtained at the end of a first step of Cu pillar plating from each first track 531a, to form first copper vias 532a, similarly to the pillar plating step described in relation with FIG. 4B, and of a step of etching of first seed layer 541a, similarly to the etch step described in relation with FIG. 4C.

FIG. 5C illustrates a structure obtained at the end: of a first step of molding of the first tracks 531a, of plating lines 536a, and of the first vias 532a by means of a molding resin, thus forming a first insulating layer 521a on top of and around said first metal tracks, of said plating lines, and of said first vias, similarly to the step described in relation with FIG. 4D; and then of a first polishing step, similarly to the polishing step described in relation with FIG. 4E.

A first level N1 of interconnection network 530a is thus obtained.

A second interconnection level N2 may then be formed by repeating again the steps of FIGS. 5A to 5C, but without forming second plating lines, as described in the following in relation with FIGS. 5D and 5E. According to a variant, second plating lines may be formed at one or a plurality of edges of the structure, at the same time as the second copper tracks at the second interconnection level, for example if this is necessary to ensure an electric continuity for the forming by electroplating of tracks and/or of metal vias of the second interconnection level.

FIG. 5D illustrates a structure obtained at the end of a second step of Cu pattern plating on first insulating layer 521a to form second copper tracks 533a, and then of a second step of Cu pillar plating from each second track 533a to form second copper vias 534a.

FIG. 5E illustrates a structure obtained at the end of a second step of molding of the second tracks 533a and of the second vias 534a by means of the molding resin, thus forming a second insulating resin layer 522a, and then of a second polishing step.

A second level N2 of interconnection network 530a is thus obtained. More than two levels could thus be formed.

FIG. 5F illustrates a structure obtained at the end of a third Cu pattern plating on second insulating layer 522a to form third copper tracks 535a.

Third tracks 535a form protrusions above second insulator layer 522a, and are not embedded in the molding resin, which for example enables to electrically couple the substrate with another component and/or to couple two components together via said substrate.

This other method example enables to do away with certain seed layer etching steps.

The obtained structure, visible in FIG. 5F, can be distinguished from the substrate 300 or FIG. 3 mainly by the presence of plating lines 536a, 536b. The presence of these plating lines at edges of structure 500 may facilitate a substrate finishing step, for example, a step of plating of the upper surface and/or of the lower surface of the structure, in particular in the case of a nickel-gold plating by electroplating, allowing an electric continuity.

A plurality of structures can thus be manufactured simultaneously and similarly in both directions of the XY plane, for example, within a panel. This may in particular enable to share electric links to perform electroplatings. The panel may be then cut into a plurality of strips. The strips may be cut into a plurality of units. During a cutting of the structure into strips or units, it may be provided to remove these plating lines by adapting the cutting width to the width of said lines, as illustrated by the dotted arrows and vertical lines.

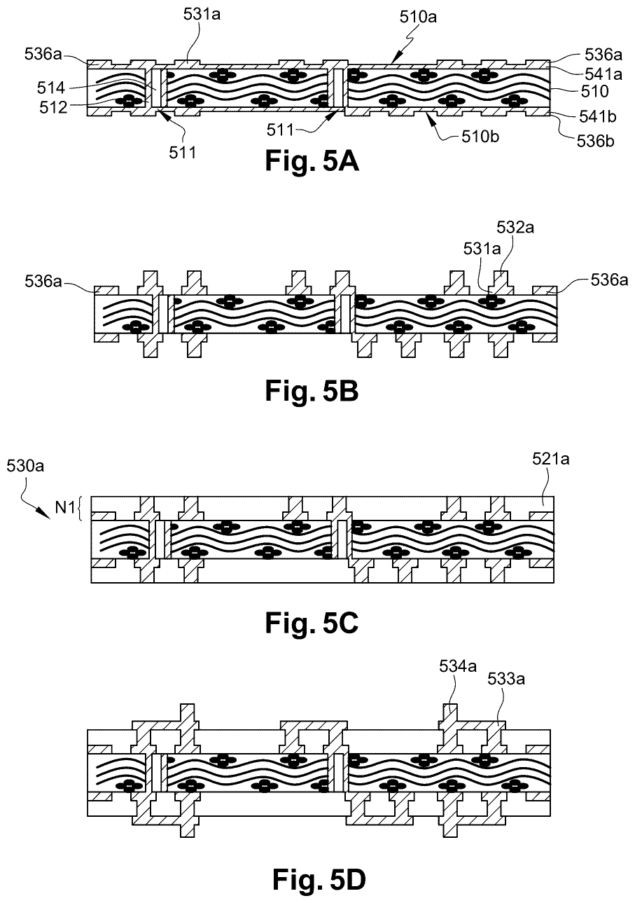

FIG. 6 is a cross-section view illustrating a complementary step of an alternative method of manufacturing a substrate 600 according to an embodiment.

This variant is described as a variant to the method of FIGS. 3A to 3M, but it may apply to any other manufacturing method example, and more widely to a manufacturing method according to a manufacturing mode.

It comprises a complementary step, subsequent to the forming of protruding metal tracks 335a, 335b, of forming of a solder mask layer 652a, 652b on the last insulator layer 322a, 322b and on said protruding metal tracks, either on each of the upper and lower surfaces 600a and 600b of substrate 600, as shown, or on a single one of these surfaces. This solder mask layer may be removed afterwards and/or be partially etched to define areas of access to certain protruding metal tracks.

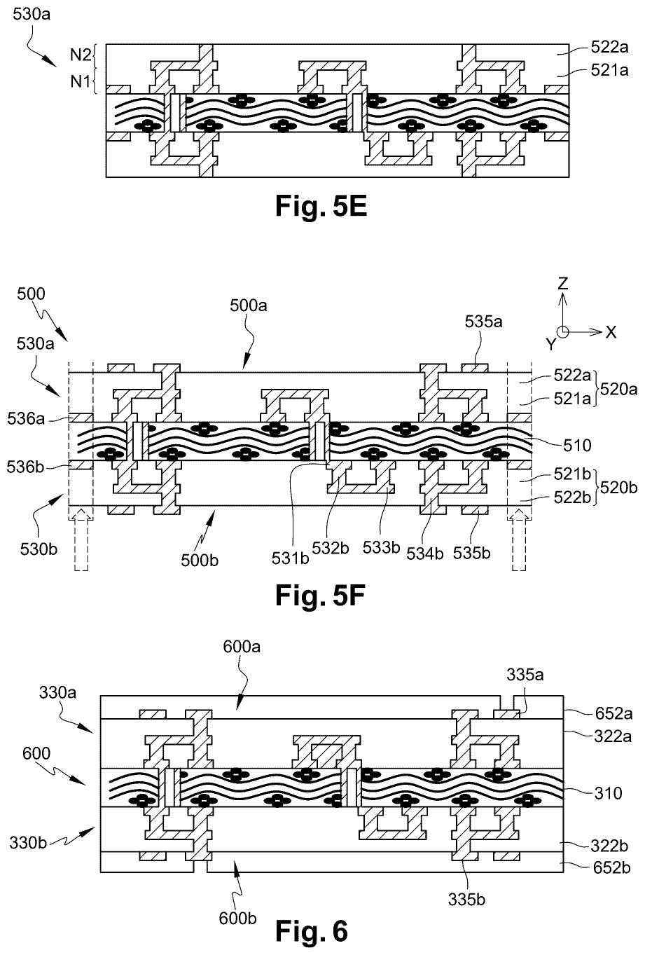

In FIGS. 3 to 6, the upper and lower interconnection networks are substantially symmetrical, particularly they have a same number of levels, but this configuration is not limiting. An example is given in FIG. 7, which shows a substrate 700 where upper interconnection network 730a has a single level N1, while lower interconnection network 730b has two levels N1, N2. Other configurations will occur to those skilled in the art.

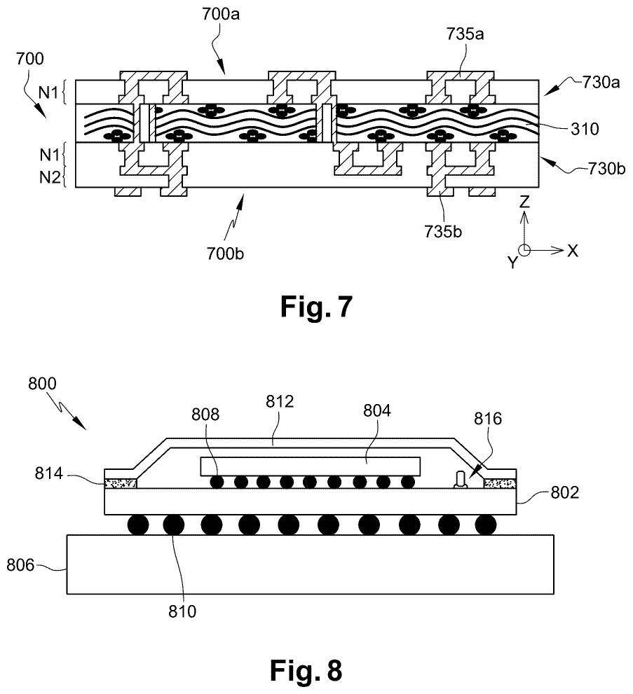

FIG. 8 is a cross-section view showing an electronic circuit 800 comprising an interconnection substrate 802, which may be selected from among one of the previously-described substrates 300, 500, 600, 700 or more widely be a substrate according to an embodiment. This shows an example of assembly capable of implementing a substrate according to an embodiment.

Substrate 802 forms an intermediate product enabling to assemble an integrated circuit chip 804 with a printed circuit 806 (PCB) according to a flip-chip assembly technique. Alternately, the chip may be assembled by a wire bonding technique.

Chip 804 is assembled to substrate 802 via bumps 808 connecting pads formed in a contact surface of chip 804 to pads formed in a contact surface of substrate 802, for example, the tracks 335a of the substrate 300 of FIG. 3.

Substrate 802 is assembled to PCB 806 via bumps 810 connecting pads formed in a contact surface of PCB substrate 806 to pads formed in another contact surface of substrate 802, for example, the tracks 335b of the substrate 300 of FIG. 3.

These two assemblies may be designated by the term “Ball Grid Array” (BGA).

Chip 804 may be encapsulated in a cover 812 assembled to substrate 802, for example, by means of an adhesive 814. Other components, for example, a component 816 of surface mount type, may be encapsulated and assembled to the substrate.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

1. A method of manufacturing an interconnection substrate, comprising:
providing a thermomechanical support formed by a fiber reinforced organic material crossed by at least one electric interconnection hole;
forming at least one level of a first interconnection network on a first surface of the thermomechanical support, wherein the first interconnection network is electrically coupled to a first end of the at least one interconnection hole;
forming at least one level of a second interconnection network on a second surface of the thermomechanical support, wherein the second interconnection network is electrically coupled to a second end of the at least one electric interconnection hole, wherein forming each level of the interconnection network comprises:
forming at least one metal track by plating to produce at least one metal via by pillar plating from said at least one metal track; and
then coating said at least one metal track and said at least one metal via in an insulating resin layer, said coating being configured to make the an upper surface of the at least one metal via flush with a surface of said insulating resin layer most distant from the thermomechanical support; and
forming at least one protruding metal track which protrudes from the insulating resin layer of a last level of each interconnection network,
wherein the metal vias are configured to electrically couple together two adjacent levels and/or the last level with the at least one protruding metal track.

2. The method according to claim 1, wherein coating comprises:
molding a material for the insulating resin layer to embed said at least one metal track and said at least one metal via; and
polishing the material after molding to make the at least one metal via flush with the surface of said molding insulating resin layer most distant from the thermomechanical support.

3. The method according to claim 1, further comprising:
coating each of the first and second surfaces of the thermomechanical support with a first seed layer;
wherein forming the first level of each interconnection network comprises:
forming at least one first metal track by pattern plating from the first seed layer;
forming at least one first metal via by pillar plating from said at least one first metal track;
removing at least a portion of the first seed layer; and
then coating said at least one first metal track and said at least one first metal via in an insulating resin to form a first insulating resin layer.

4. The method according to claim 3, further comprising:
forming a second level of one or more of the first and second interconnection networks;
wherein forming the second level comprises:
forming a second seed layer on the first molding insulating resin layer;
forming at least one second metal track by pattern plating from the second seed layer;
forming at least one second metal via by pillar plating from said at least one second metal track;
removing at least a portion of the second seed layer; and
then coating said at least one second metal track and said at least one second metal via in an insulating resin to form a second insulating resin layer.

5. The method according to claim 4, further comprising forming at least one third level of one or more of the first and second interconnection networks, wherein forming the third level comprises repeating of the steps of claim 3.

6. The method according to claim 1, further comprising, when forming at least one interconnection level of the first and the second interconnection networks, forming of at least one plating line configured to ensure an electric continuity outside of the substrate for use in connection with forming by plating of a metal track and/or metal via.

7. The method according to claim 6, further comprising:
coating each of the first and second surfaces of the thermomechanical support with a first seed layer;
wherein forming the first level of each interconnection network comprises:
forming at least one first metal track by pattern plating from the first seed layer;
forming at least one first metal via by pillar plating from said at least one first metal track;
removing at least a portion of the first seed layer; and
then coating said at least one first metal track and said at least one first metal via in an insulating resin to form a first insulating resin layer.

8. The method according to claim 7, further comprising:
forming a second level of one or more of the first and second interconnection networks;
wherein forming the second level comprises:
forming at least one second metal track by pattern plating on the first molding insulating resin layer;
forming at least one second metal via by pillar plating from said at least one second metal track; and
then coating said at least one second metal track and said at least one second metal via in an insulating resin to form a second insulating resin layer.

9. The method according to claim 8, comprising forming at least one third level of one or more of the first and second interconnection networks, wherein forming the third level comprises repeating of the steps of claim 7.

10. The method according to claim 1, wherein the plating comprises performing one of an electroplating or an electrolytic growth.

11. The method according to claim 1, wherein pattern plating and pillar plating are performed through a pattern comprising at least one opening.

12. The method according to claim 1, wherein the first interconnection network and the second interconnection network have a same quantity of levels.

13. The method according to claim 1, wherein the first interconnection network and the second interconnection network have different quantities of levels.

14. The method according to claim 1, wherein the metal tracks and the metal vias are made of a material selected from the group consisting of: copper, nickel, tungsten, and aluminum.

15. The method according to claim 1, wherein the insulating resin layer is made of a material selected from the group consisting of: an epoxy resin and a thermosetting resin.

16. The method according to claim 1, wherein coating said at least one second metal track and said at least one second metal via in the insulating resin layer comprises initially providing a material for the insulating resin layer in the form of a powder to cover said at least one second metal track and said at least one second metal via.

17. The method according to claim 1, wherein coating said at least one second metal track and said at least one second metal via in the insulating resin layer comprises initially providing a material for the insulating resin layer in the form of a film to cover said at least one second metal track and said at least one second metal via.

18. The method according to claim 1, wherein coating said at least one second metal track and said at least one second metal via in the insulating resin layer comprises initially providing a material for the insulating resin layer in the form of a liquid to cover said at least one second metal track and said at least one second metal via.

19. The method according to claim 1, wherein the molding resin is made of a material different than the fiber reinforced organic material.
